(19) United States
(12) Patent Application Publication
(10) Pub. No.: US 2025/0126855 A1
(43) Pub. Date: Apr. 17, 2025

(54) GATE FORMATION PROCESS

(71) Applicant: Taiwan Semiconductor Manufacturing Company, Ltd., Hsinchu (TW)

(72) Inventors: Ming-Huei Lin, Hsinchu City (TW); Kai-Yuan Cheng, Hsinchu County (TW); Chih-Pin Tsao, Hsinchu County (TW); Hsing-Kan Peng, Hsinchu County (TW); Shih-Hsun Chang, Hsinchu (TW); Shu-Hui Wang, Hsinchu City (TW); Jeng-Ya Yeh, New Taipei City (TW)

(21) Appl. No.: 18/485,602

(22) Filed: Oct. 12, 2023

(51) Int. Cl. H01L 29/06; H01L 21/8234; H01L 27/088; H01L 29/423; H01L 29/66; H01L 29/775; H01L 29/786

(52) U.S. Cl. CPC H10D 62/118; H10D 30/014; H10D 30/43; H10D 30/6735; H10D 30/6757; H10D 64/017; H10D 84/0128; H10D 84/0135; H10D 84/038; H10D 84/83

(57) ABSTRACT

Methods for forming a gate structure of a multi-gate device are provided. An example method includes depositing a gate dielectric layer over first nanostructures over a first region of a substrate and second nanostructures over a second region of the substrate, depositing a first work function metal (WFM) layer over the first nanostructures and the second nanostructures, depositing a first hard mask (HM) layer over the first WFM layer, selectively removing the first HM layer and the first WFM layer over the first region, selectively removing the first HM layer over the second region, depositing a second WFM layer over the substrate, depositing a second HM layer over the second WFM layer, selectively removing the second HM layer and the second WFM layer over the first region, selectively removing the second HM layer over the second region, and depositing a third WFM layer over the substrate.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. Due to this configuration, a GAA transistor may also be referred to as a surrounding-gate transistor (SGT) or a multi-bridge-channel (MBC) transistor. The channel region of the GAA transistor may be formed from nanowires, nanosheets, other nanostructures, and/or other suitable structures. These shapes of the channel region also give a GAA transistor different names. For example, a GAA transistor with nanosheet channel regions may be referred to as a nanosheet transistor.

When GAA transistors of different conductivity types or different threshold voltages are desired, gate formation processes may involve depositing more than one work function metal layers in different device regions. As device dimensions continue to reduce, it may become more and more challenging to satisfactorily and selectively depositing certain work function metal layers in one region and certain other work function metal layers in another region.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor device according to an embodiment of the present disclosure.

FIGS. 2-26 illustrate fragmentary cross-sectional views of the first area and the second area of the workpiece at various stages of fabrication in accordance with the method in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Multi-gate devices, such as GAA transistors have been introduced to improve gate control by increasing gate-channel coupling, reducing off-state current, and reducing short-channel effects (SCEs). A GAA transistor has a gate structure that extends, partially or fully, around a channel region to provide access to the channel region on two or more sides. A channel region of a GAA transistor may include multiple sheet-like or wire-like nano-size channel members that are stacked one over another or placed side by side. As device dimensions continue to shrink, formation of a gate structure to satisfactorily wrap around each of the channel members can be quite challenging. Not only that, in order to form GAA transistors with different threshold voltages, different work function metal (WFM) layers have to be deposited over different regions to wrap around each of the channel members. To successfully depositing different WFM layers in different regions, WFM layers need to fill up the space between channel members and a gate trench that exposes the channel members has to be large enough to accommodate patterning materials. Some processes aim for increasing the spacing for patterning materials but too much patterning materials may result in incomplete removal of the patterning materials and unsatisfactory filling of the WFM layers.

The present disclosure relates to formation of gate structures for p-type GAA transistors and n-type GAA transistors on a substrate. A workpiece that includes first nanostructures over a first region and second nanostructures over a second region. After forming an interfacial layer and a gate dielectric layer over surfaces of the first nanostructures and the second nanostructures, a first work function metal (WFM) layer is deposited over the first region and the second region. After the deposition of the first WFM layer, a first hard mask layer is deposited over the first WFM layer. After trimming the first hard mask layer, the first hard mask layer and the first WFM layer over the first region is selectively removed. The first hard mask layer over the second region is then selectively removed. A second WFM layer is deposited over the first region and the second region and a second hard mask layer is deposited over the second WFM layer. After trimming the second hard mask layer, the second hard mask layer and the WFM layer are selectively removed from the first region. Afterwards, a third WFM is deposited over the first region and the second region. By depositing the first WFM layer and the second WFM layer over the second region by using two separate hard masks, the process window for the gate fill process is widened.

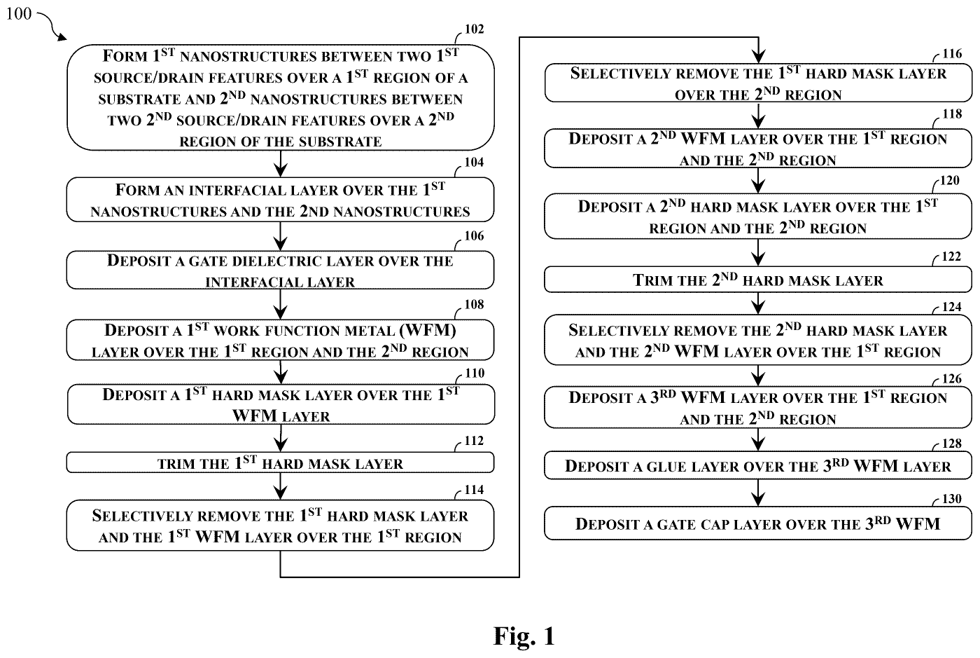

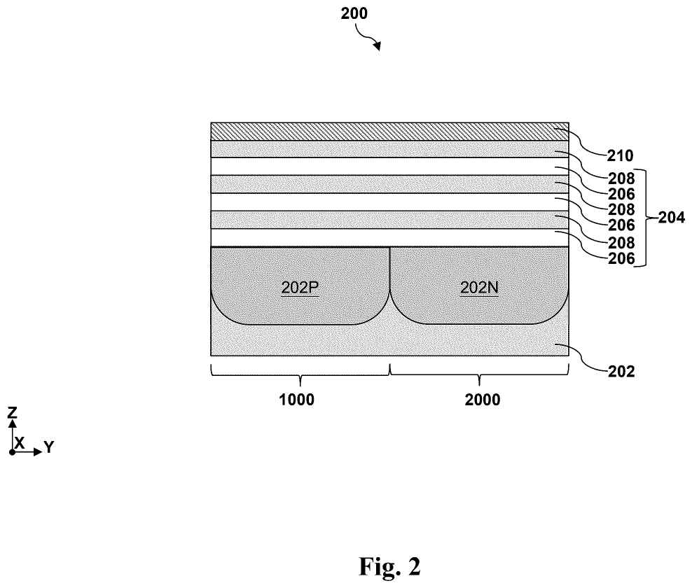

The various aspects of the present disclosure will now be described in more detail with reference to the figures. In that regard, FIG. 1 is a flowchart illustrating method 100 for forming gate structures for a stacked multi-gate device according to various aspects of the present disclosure. Method 100 is merely an example and is not intended to limit the present disclosure to what is explicitly illustrated in method 100. Additional steps may be provided before, during and after method 100 and some steps described can be replaced, eliminated, or moved around for additional embodiments of the method. Not all steps are described herein in detail for reasons of simplicity. Method 100 is described below in conjunction with FIGS. 2-26, which are fragmentary cross-sectional views of a workpiece 200 at different stages of fabrication according to embodiments of method 100. Because the workpiece 200 will be fabricated into a semiconductor device 200 upon conclusion of the fabrication processes, the workpiece 200 may be referred to as the semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively dependent upon the context.

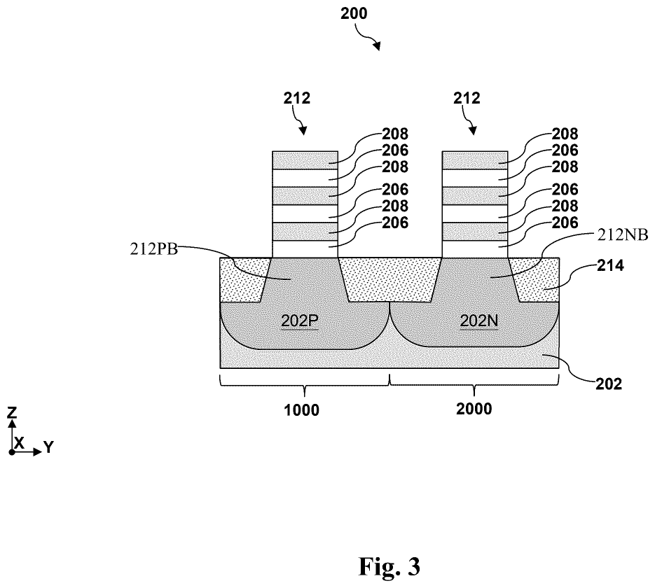

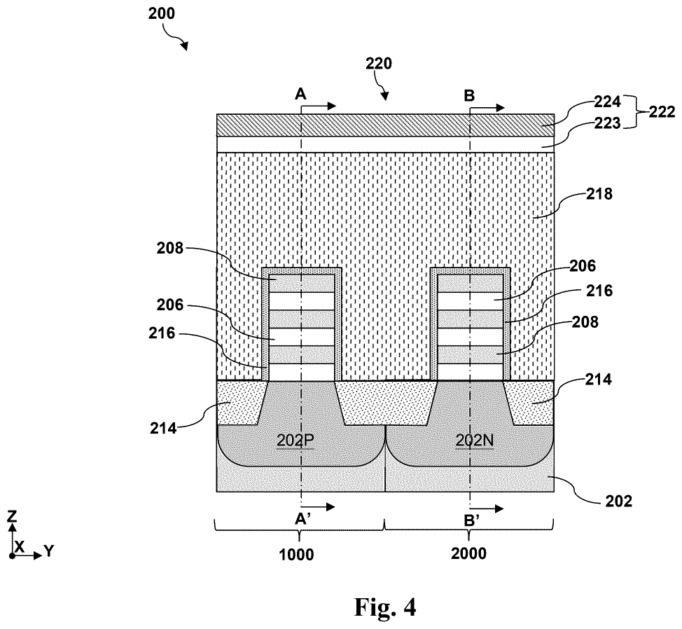

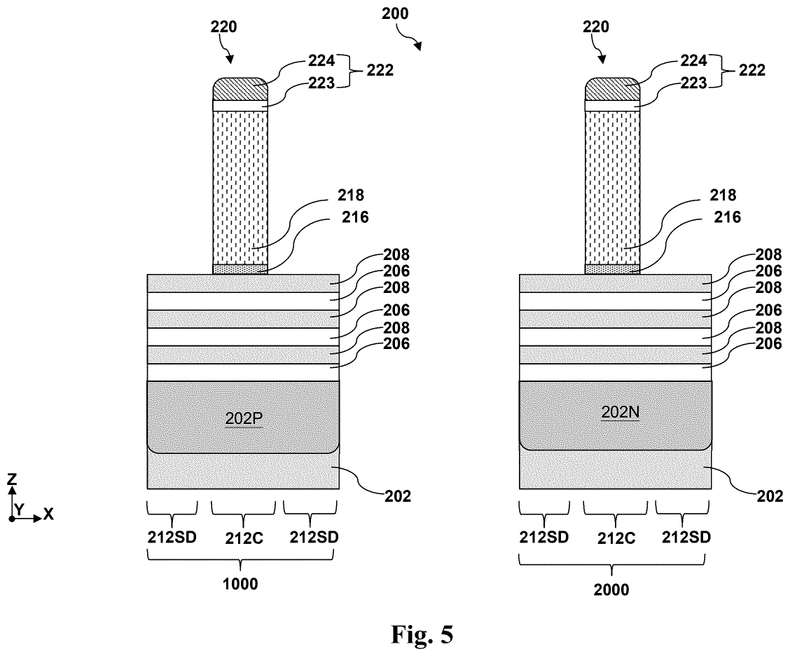

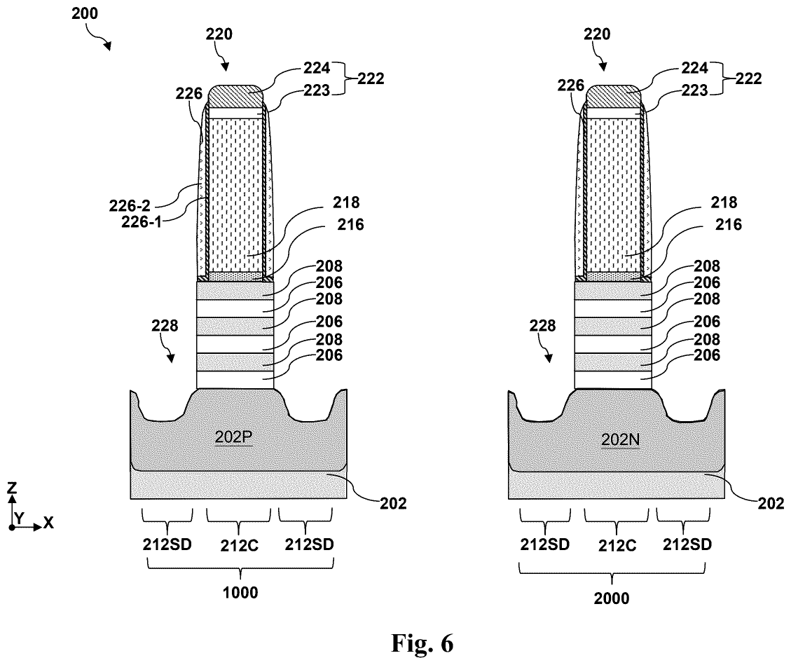

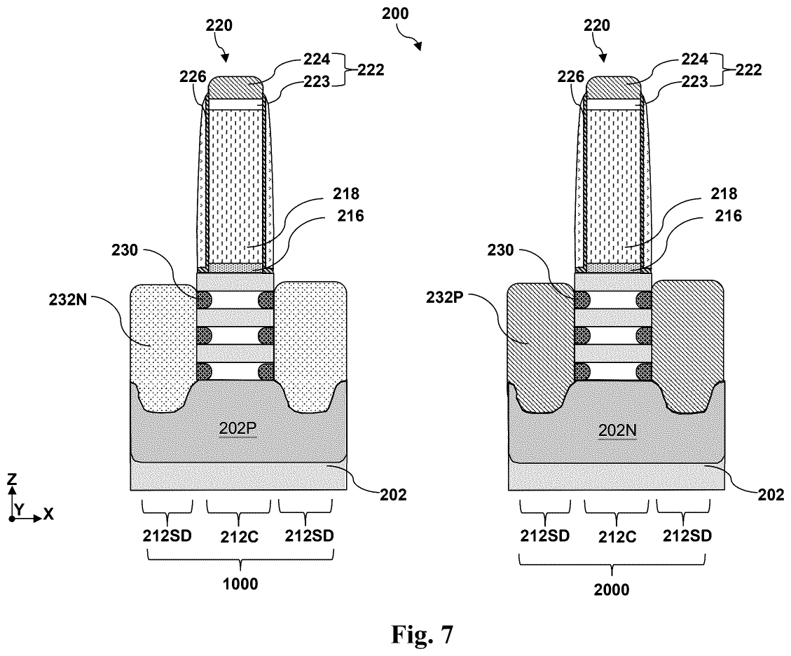

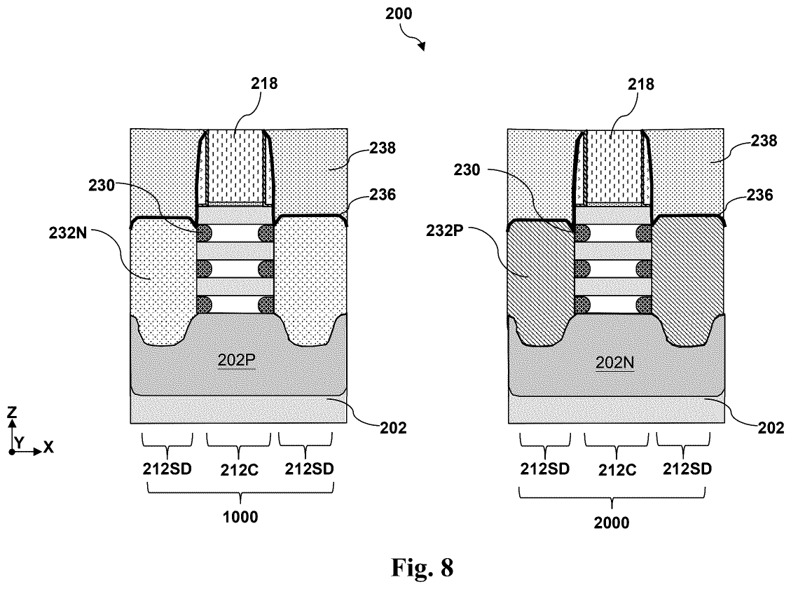

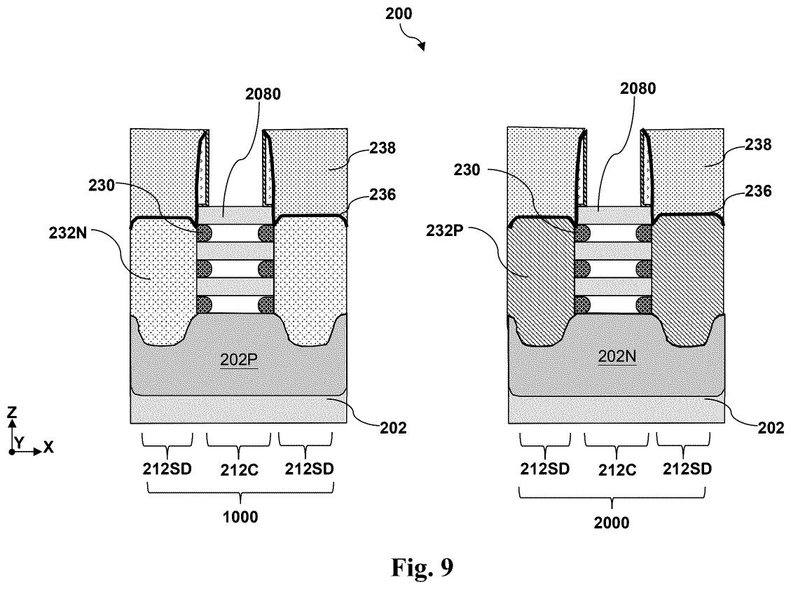

Referring to FIGS. 1-9, method 100 includes a block 102 where first nanostructures 2080 are formed between two first source/drain features 232N over a first region 1000 of a substrate 202 and second nanostructures 2080 are formed between two second source/drain features 232P over a second region 2000 of the substrate 202. Operations at block 102 includes formation of a stack 204 over a substrate 202 (shown in FIG. 2), patterning of the stack 204 and a portion of the substrate 202 to form a fin-shaped structure 212 (shown in FIG. 3), formation of a dummy gate stack 220 over channel regions of the fin-shaped structure 212 (shown in FIGS. 4 and 5), formation of a gate spacer 226 and recessing of source/drain regions 212SD of the fin-shaped structure 212 (shown in FIG. 6), formation of first source/drain features 232N and second source/drain features 232P (shown in FIG. 7), deposition of a contact etch stop layer (CESL) 236 and an interlayer dielectric (ILD) layer 238 (shown in FIG. 8), and removal of the dummy gate stack 220 and release of the first nanostructures 2080 and second nanostructures 2080 in the first region 1000 and the second region 2000 (shown in FIG. 9).

Referring to FIG. 2, the substrate 202 is part of a workpiece 200 that undergoes the various operations of method 100. In some embodiments, the substrate 202 may be a semiconductor substrate such as a silicon (Si) substrate. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features. The substrate 202 may include various doping configurations depending on design requirements as is known in the art. In the depicted embodiments, the substrate 202 includes a first region 1000 and a second region 2000. The substrate 202 includes a p-type well 202P (i.e., a p-type dopant profile) over the first region 1000 and an n-type well 202N (i.e., an n-type doping profile) over the second region 2000. In some implementations, the n-type dopant for forming the n-type well 202N may include phosphorus (P) or arsenic (As) and the p-type dopant for forming the p-type well 202P may include boron (B). The suitable doping for the n-type well 202N or the p-type well 202P may include ion implantation of dopants and/or diffusion processes.

Referring still to FIG. 2, the stack 204 includes sacrificial layers 206 of a first semiconductor composition interleaved by channel layers 208 of a second semiconductor composition. The first and second semiconductor compositions may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

In some embodiments, all sacrificial layers 206 may have a substantially uniform first thickness between about 5 nm and about 10 nm and all of the channel layers 208 may have a substantially uniform second thickness between about 2 nm and about 8 nm. The first thickness and the second thickness may be identical or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes at a temperature between about 600° C. and about 800° C. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204.

Referring FIG. 3, a fin-shaped structure 212 is formed from the stack 204 and a portion of the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shaped structure 212 may be patterned from the stack 204 and a portion of the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process forms trenches extending through the stack 204 and a portion of the substrate 202. The trenches define the fin-shaped structures 212, including base fins (first base fin 212PB and a second base fin 212NB are shown in FIG. 3) formed from the substrate 202. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212, along with the sacrificial layers 206 and the channel layers 208 therein, extends vertically along the Z direction and lengthwise along the X direction.

An isolation feature 214 is formed adjacent the fin-shaped structure 212. In some embodiments, the isolation feature 214 may be formed in the trenches to isolate the fin-shaped structures 212 from a neighboring active region, which may be another fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. As shown in FIG. 3, while the base fins (including the first base fin 212PB and the second base fin 212NB) are disposed in or surrounded by the STI feature 214, the rest of the fin-shaped structure 212 that is formed from the stack 204 rises above the STI feature 214 after the recessing.

Reference is now made to FIGS. 4 and 5. A dummy gate stack 220 is formed over a channel region 212C of the fin-shaped structure 212. In some embodiments, a gate replacement process (or gate-last process) is adopted where the dummy gate stack 220 serves as a placeholder to undergo various processes and is to be removed and replaced by the functional gate structure. Other processes and configuration are possible. In some embodiments illustrated in FIG. 5, the dummy gate stack 220 is formed over the fin-shaped structure 212 and the fin-shaped structure 212 in the first region 1000 and the second region 2000 may be each divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be deposited over the workpiece 200. In some embodiments, the dummy dielectric layer 216 may be formed on the fin-shaped structure 212 using a chemical vapor deposition (CVD) process, an ALD process, an oxygen plasma oxidation process, a thermal oxidation process, or other suitable processes. In some instances, the dummy dielectric layer 216 may include silicon oxide. When the dummy dielectric layer 216 is formed using an oxidation process, it may be selectively formed on exposed surfaces of the fin-shaped structure 212, as illustrated in FIG. 4. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shaped structure 212.

Referring now to FIG. 6, at least one gate spacer layer 226 is deposited over the dummy gate stack 220 in the first region 1000 and the second region 2000. In some embodiments, the at least one gate spacer layer 226 is deposited conformally over the workpiece 200, including over top surfaces and sidewalls of the dummy gate stack 220. The term “conformally” may be used herein for ease of description of a layer having substantially uniform thickness over various regions. The at least one gate spacer layer 226 may be a single layer or a multi-layer. In the depicted embodiments, the at least one gate spacer layer 226 includes a first spacer layer 226-1 and a second spacer layer 226-2 disposed over the first spacer layer 226-1. A composition of the first spacer layer 226-1 may be different from a composition of the second spacer layer 226-2. In some implementation, a dielectric constant of the first spacer layer 226-1 is greater than a dielectric constant of the second spacer layer 226-2. The at least one gate spacer layer 226, including the first spacer layer 226-1 and the second spacer layer 226-2, may include silicon oxide, silicon carbonitride, silicon oxycarbide, silicon oxycarbonitride, or silicon nitride. The at least one gate spacer layer 226 may be deposited over the dummy gate stack 220 using processes such as, a CVD process, a subatmospheric CVD (SACVD) process, an ALD process, or other suitable process. For ease of reference, the at least one gate spacer layer 226 may also be referred to the gate spacer layer 226 for simplicity.

Referring still to FIG. 6, source/drain regions 212SD of the fin-shaped structure 212 are recessed to form source/drain trenches 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIG. 6, the source/drain regions 212SD of the fin-shaped structure 212 are recessed to expose sidewalls of the sacrificial layers 206 and the channel layers 208. In some implementations, the source/drain trenches 228 extend below the stack 204 into the substrate 202.

Referring to FIG. 7, inner spacer features 230 are formed. After the formation of the source/drain trenches 228, the sacrificial layers 206 in the channel regions 212C are selectively and partially recessed to form inner spacer recesses, while the exposed channel layers 208 are substantially unetched. In an embodiment where the channel layers 208 consist essentially of silicon (Si) and sacrificial layers 206 consist essentially of silicon germanium (SiGe), the selective and partial recess of the sacrificial layers 206 may include a SiGe oxidation process followed by a SiGe oxide removal. In that embodiment, the SiGe oxidation process may include use of ozone (O₃). In some other embodiments, the selective recess may be a selective isotropic etching process (e.g., a selective dry etching process or a selective wet etching process), and the extent at which the sacrificial layers 206 are recessed is controlled by duration of the etching process. The selective dry etching process may include use of one or more fluorine-based etchants, such as fluorine gas or hydrofluorocarbons. The selective wet etching process may include an APM etch (e.g., ammonia hydroxide-hydrogen peroxide-water mixture). After the formation of the inner spacer recesses, an inner spacer material layer is deposited over the workpiece 200, including in the inner spacer recesses. The inner spacer material layer may include silicon oxide, silicon nitride, silicon oxycarbide, silicon oxycarbonitride, silicon carbonitride, metal nitride, or a suitable dielectric material and may be deposited using CVD, PECVD, SACVD, ALD or other suitable methods. The deposited inner spacer material layer is then etched back to remove excess inner spacer material layer over the gate spacer layer 226 and sidewalls of the channel layers 208, thereby forming the inner spacer features 230. In some embodiments, the etch back process to form the inner spacer features 230 may be a dry etch process that includes use of an oxygen-containing gas, hydrogen (H₂), nitrogen (N₂), a fluorine-containing gas (e.g., NF₃, CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof. While not explicitly shown, a cleaning process may be performed after the etch back process to remove native oxide and debris from surfaces of the channel layers 208.

Reference is still made to FIG. 7. First source/drain features 232N are formed over source/drain regions 212SD in the first region 1000 and second source/drain features 232P are formed over source/drain regions 212SD in the second region 2000. Each of the first source/drain features 232N and the second source/drain features 232P may be epitaxially and selectively formed from the exposed sidewalls of the channel layers 208 and exposed surfaces of the substrate 202, while sidewalls of the sacrificial layers 206 remain covered by the inner spacer features 230. Suitable epitaxial processes for formation of the first source/drain features 232N and the second source/drain features 232P include vapor-phase epitaxy (VPE), ultra-high vacuum CVD (UHV-CVD), molecular beam epitaxy (MBE), and/or other suitable processes. The epitaxial growth process may use gaseous precursors, which interact with the composition of the substrate 202 and the channel layers 208. In some embodiments, parameters of the epitaxial growth process are selected such that the first source/drain features 232N and the second source/drain features 232P are not epitaxially deposited on the inner spacer features 230. That said, the overgrowth of the first source/drain features 232N and the second source/drain features 232P may merge over some of the inner spacer feature 230.

The first source/drain features 232N and the second source/drain features 232P may have different conductivity types and may each include more than one epitaxial layers. In some embodiments represented in FIG. 7, the first source/drain features 232N over the first region 1000 may be n-type source/drain features that include silicon (Si) doped with an n-type dopant, such as phosphorus (P) or arsenic (As) and second source/drain features 232P over the second region 2000 may be p-type source/drain features that include silicon germanium (SiGe) doped with a p-type dopant, such as boron (B). When each of the first source/drain features 232N includes multiple epitaxial layers, the epitaxial layer closer to the channel layers 208 and the substrate 202 may include lower n-type dopant concentrations and the epitaxial layer(s) away from the channel layers 208 and the substrate may include higher n-type dopant concentrations. Similarly, when each of the first source/drain features 232N includes multiple epitaxial layers, the epitaxial layer closer to the channel layers 208 and the substrate 202 may include lower p-type dopant concentrations and the epitaxial layer(s) away from the channel layers 208 and the substrate may include higher p-type dopant concentrations. Additionally, when each of the first source/drain features 232N includes multiple epitaxial layers, the epitaxial layer closer to the channel layers 208 and the substrate 202 may include lower germanium (Ge) contents and the epitaxial layer(s) away from the channel layers 208 and the substrate may include higher germanium (Ge) contents. Because the first source/drain features 232N and the second source/drain features 232P have different compositions and are formed in different regions, they are formed separately. In one embodiments, a patterned mask layer, such as a photoresist layer or a bottom antireflective coating (BARC) layer, may be formed to cover the second region 2000, while the first source/drain features 232N are formed in the first region 1000. Then another patterned mask layer may be formed to cover the first region 1000, while the second source/drain features 232P are formed in the second region 2000. In another embodiment, the order may be switched and the second source/drain features 232P are first formed in the second region 2000. While not explicitly shown in the figures, an anneal process may be performed to obtain a desired electronic contribution of the dopant in the semiconductor host, such as silicon germanium (SiGe) or silicon (Si). The anneal process may include a rapid thermal anneal (RTA) process, a laser spike anneal process, a flash anneal process, or a furnace anneal process. The anneal process may include a peak anneal temperature between about 900° C. and about 1000° C. In these implementations, the peak anneal temperature may be maintained for a duration measured by seconds or microseconds.

Referring to FIG. 8, a contact etch stop layer (CESL) 236 and an interlayer dielectric (ILD) layer 238 are deposited over the first source/drain features 232N and the second source/drain features 232P. The CESL 236 may include silicon nitride, silicon oxynitride, and/or other materials known in the art. The ILD layer 238 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. In some embodiments, the CESL 236 is first conformally deposited over the first region 1000 and the second region 2000 by CVD, ALD, plasma-enhanced chemical vapor deposition (PECVD) process and/or other suitable deposition or oxidation processes and the ILD layer 238 is deposited over the CESL 236 by spin-on coating. FCVD, CVD, or other suitable deposition technique. In some embodiments, after formation of the ILD layer 238, the workpiece 200 may be annealed to improve integrity of the ILD layer 238. As shown in FIG. 8, after the deposition of the CESL 236 and the ILD layer 238, a planarization process, such as a chemical mechanical polishing (CMP) process, may be performed to remove excess materials. As shown in FIG. 8, the planarization process also exposes the dummy electrode layer 218 of the dummy gate stacks 220 in the first region 1000 and the second region 2000.

Reference is now made to FIG. 9. The exposed dummy gate stacks 220 are removed and sacrificial layers 206 in the channel regions 210C are selectively removed to release the first nanostructures 2080 in the first region 1000 and the second nanostructures 2080 in the second region 2000. The removal of the dummy gate stacks 220 may include one or more etching processes that are selective to the material in the dummy gate stacks 220. For example, the removal of the dummy gate stacks 220 may be performed using as a selective wet etch, a selective dry etch, or a combination thereof. After the removal of the dummy gate stacks 220, sidewalls of the channel layers 208 and sacrificial layers 206 in the channel regions 210C are exposed. Thereafter, the sacrificial layers 206 in the channel regions 210C are selectively removed to release the first nanostructures 2080 in the first region 1000 and the second nanostructures 2080 in the second region 2000. The first nanostructures 2080 in the first region 1000 and the second nanostructures 2080 in the second region 2000 may also be referred to as channel members. The selective removal of the sacrificial layers 206 may be implemented by selective dry etch, selective wet etch, or other selective etch processes. In some embodiments, the selective wet etching includes an APM etch (e.g., ammonia hydroxide-hydrogen peroxide-water mixture). In some other embodiments, the selective removal includes SiGe oxidation followed by a silicon germanium oxide removal. For example, the oxidation may be provided by ozone clean and then silicon germanium oxide removed by an etchant such as NH₄OH.

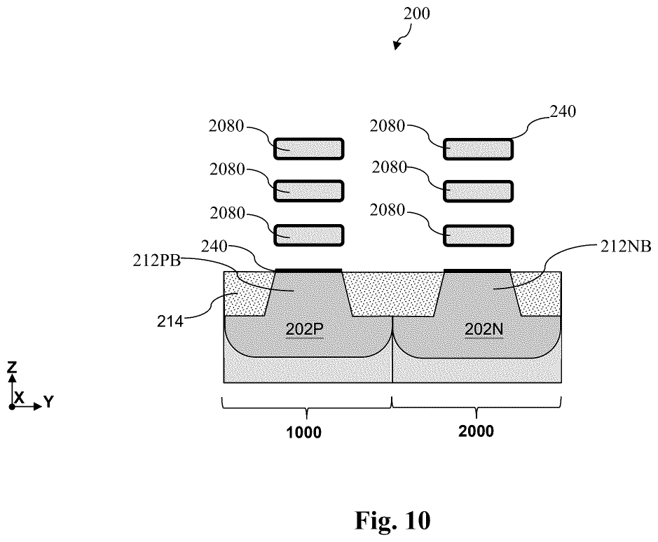

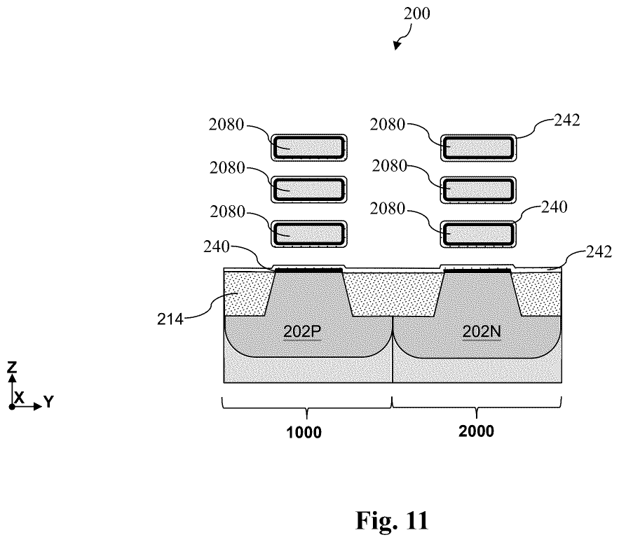

Referring to FIGS. 1 and 10, method 100 includes a block 104 where an interfacial layer 240 is formed over the first nanostructures 2080 and the second nanostructures 2080. As shown in FIG. 10, the first nanostructures 2080 are disposed over the first base fin 212PB in the first region 1000 and the second nanostructures 2080 are disposed over the second base fin 212NB in the second region 2000. Because the first base fin 212PB is patterned from the p-type well 202P, the first base fin 212PB includes the same composition with the p-type well 202P. Because the second base fin 212NB is patterned from the n-type well 202N, the second base fin 212NB includes the same composition with the n-type well 202N. In FIG. 10, the first region 1000 may be contiguous with the second region 2000. As a result, the p-type well 202P may interface the n-type well 202N. The interfacial layer 240 may include silicon oxide or silicon oxynitride, or other suitable material. In some embodiments, the interfacial layer 240 may be deposited over surfaces of the first nanostructures 2080, surfaces of the second nanostructures, and top surfaces of the first base fin 212PB and the second base fin 212NB using a suitable method, such as atomic layer deposition (ALD), chemical vapor deposition (CVD), ozone oxidation, thermal oxidation, or other suitable method. The interfacial layer 240 serves the function to control and reduce gate leakage current and improve interfacial adhesion between the gate dielectric layer 242 (shown in FIG. 11) and the nanostructures (including the first nanostructures 2080 in the first region 1000 and the second nanostructures 2080 in the second region 2000). In the depicted embodiments, the interfacial layer 240 is formed using thermal oxidation and the interfacial layer 240 is selectively deposited on semiconductor surfaces but not on dielectric surfaces, such as the top surfaces of the isolation feature 214.

Referring to FIGS. 1 and 11, method 100 includes a block 106 where a gate dielectric layer 242 is deposited over the interfacial layer 240. In some embodiments, the gate dielectric layer 242 is high-k dielectric layer as its dielectric constant is greater than that of silicon dioxide (˜3.9). In some implementations, the gate dielectric layer 242 may include doped or undoped hafnium oxide (HfO₂), doped or undoped zirconium oxide (ZrO₂), doped or undoped titanium oxide (TiO₂), or doped or undoped aluminum oxide (Al₂O₃). For example, the gate dielectric layer 242 may include hafnium silicon oxide (HfSiO), hafnium silicon oxynitride (HfSiON), or hafnium aluminum oxide (HfAlO), hafnium tantalum oxide (HfTaO), Hafnium zirconium oxide (HfZrO), zirconium silicon oxide (ZrSiO₂), hafnium titanium oxide (HfTiO), or a combination thereof. Upon conclusion of operations at block 106, each of the first nanostructures 2080 in the first region 1000 and the second nanostructures 2080 in the second region 2000 is wrapped around by the interfacial layer 240 and the gate dielectric layer 242. Furthermore, as illustrated in FIG. 11, the deposition of the gate dielectric layer 242 may not be selectively and the gate dielectric layer 242 may be deposited over the isolation feature 214.

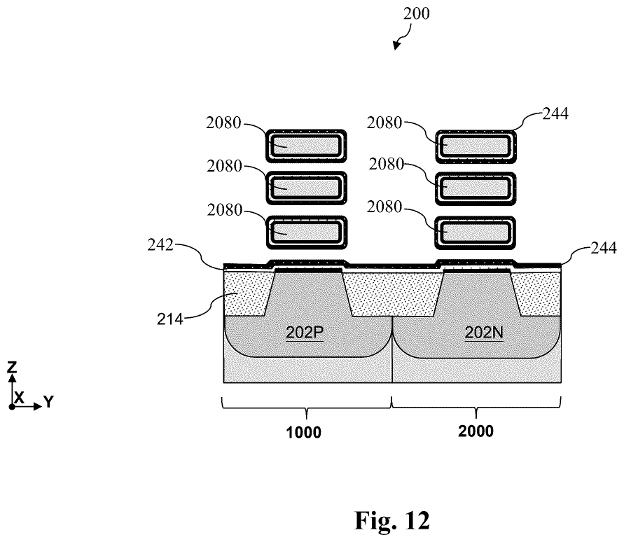

Referring to FIGS. 1 and 12, method 100 includes a block 108 where a first work function metal (WFM) layer 244 is deposited over the first region 1000 and the second region 2000. In some embodiments, the first WFM layer 244 may be a p-type WFM layer and may include titanium nitride (TiN), titanium silicon nitride (TiSiN), tantalum nitride (TaN), tungsten carbonitride (WCN), molybdenum (Mo), or other suitable p-type work function material. The first WFM layer 244 may be deposited using ALD. As show in FIG. 12, a thickness of the first WFM layer 244 is such that the spacing between two adjacent first nanostructures 2080 or second nanostructures 2080 is not completely filled.

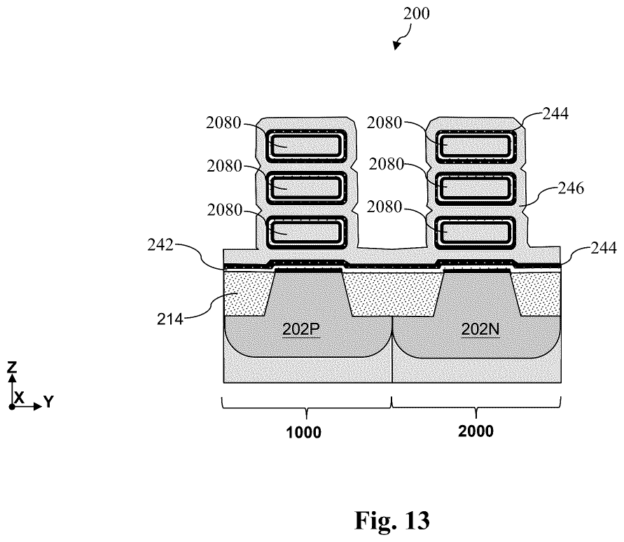

Referring to FIGS. 1 and 13, method 100 includes a block 110 where a first hard mask layer 246 is deposited over the first WFM layer 244. The first hard mask layer 246 is formed of a material that may be selectively removed without substantially damaging the first WFM layer 244. In some embodiments, the first hard mask layer 246 is formed of a dielectric material (such as silicon oxide, aluminum oxide), or a semiconductor material (such as silicon (Si) or germanium (Ge) or silicon germanium (SiGe)). In one embodiment, the first hard mask layer 246 includes aluminum oxide. The first hard mask layer 246 may be deposited using atomic layer deposition (ALD) or other suitable method. As shown in FIG. 13, the first hard mask layer 246 is formed to a thickness such that it completely fills the spacing between two adjacent first nanostructures 2080 or two adjacent second nanostructures 2080.

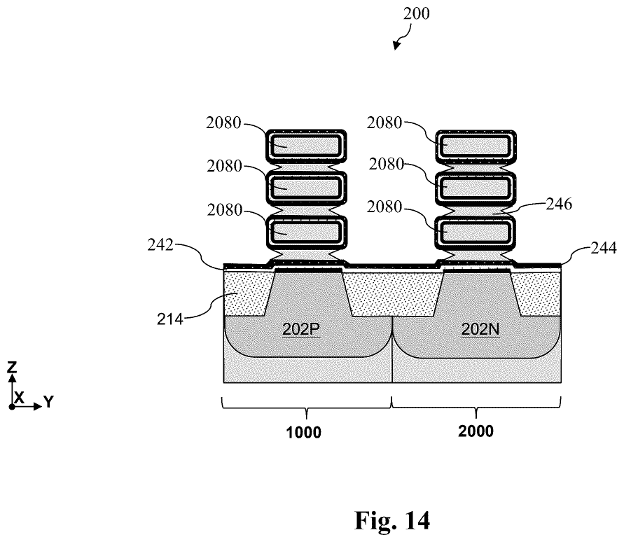

Referring to FIGS. 1 and 14, method 100 includes a block 112 where the first hard mask layer 246 is trimmed. At block 112, a dry etch process or a wet etch process may be performed to remove the first hard mask layer 246 over the workpiece 200 other than the portions disposed between two adjacent first nanostructures 2080 or two adjacent second nanostructures 2080. The suitable etch process for block 112 may be selected based on the composition of the first hard mask layer 246. For example, when the first hard mask layer 246 includes aluminum oxide, ammonium hydroxide may be used to selectively etch the first hard mask layer 246. Put differently, operations at block 112 may remove the first hard mask layer 246 over the topmost surfaces and side surfaces of the first nanostructures 2080, over the topmost surfaces and side surfaces of the second nanostructures 2080, and over the gate dielectric layer 242 over the isolation feature 214 to expose the first WFM layer 244 deposited thereover.

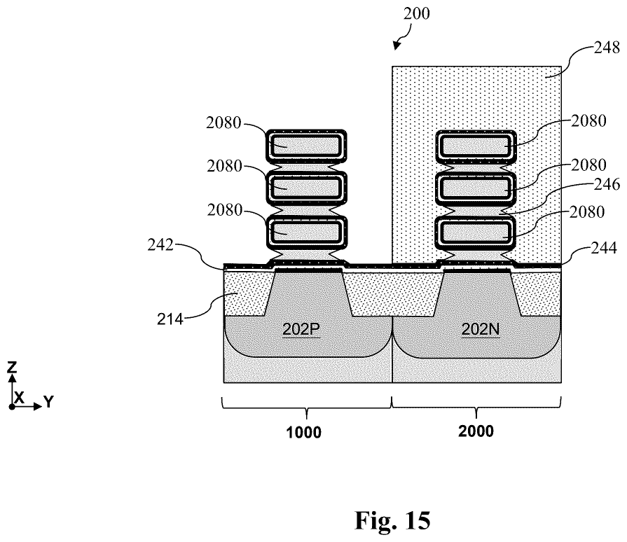

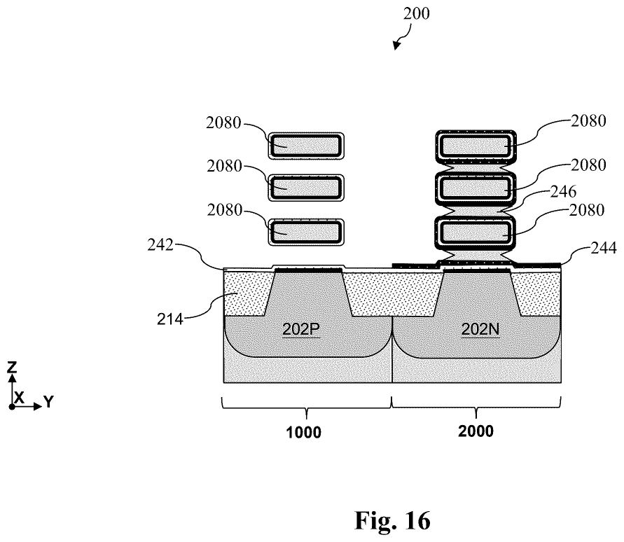

Referring to FIGS. 1, 15 and 16, method 100 includes a block 114 where the first hard mask layer 246 and the first WFM layer 244 over the first region 1000 are selectively removed. To selectively remove the first hard mask layer 246 and the first WFM layer 244 over the first region 1000, a first BARC layer 248 is formed over the second region 2000 while the first region 1000 is exposed. In an example process, a blanket BARC layer is deposited over the first region 1000 and the second region 2000, and then a photoresist layer is deposited over the blanket BARC layer. The photoresist layer is pre-baked, patterned by exposure to a patterned radiation passing through or reflected from a mask, post-baked, and developed in a developing process using a developer, to form a patterned photoresist layer. The patterned photoresist layer is used as an etch mask to pattern the blanket BARC layer to form the first BARC layer 248, as shown in FIG. 15. With the first BARC layer 248 covering the second region 2000, the first hard mask layer 246 and the first WFM layer 244 over the first region 1000 are removed. The removal of the first hard mask layer 246 and the first WFM layer 244 may be performed using one or more etching process. For example, the first hard mask layer 246 may be removed using a wet etch process that uses ammonium hydroxide or a dry etch process that uses a chlorine-containing gas (e.g., Cl₂, CHCl₃, CCl₄, and/or BCl₃). The first WFM layer 244 may be removed using a wet etch process that includes a sulfuric acid hydrogen peroxide mixture (SPM), a mixture of ammonium hydroxide and hydrogen peroxide (SC1), or a mixture of hydrochloric acid and hydrogen peroxide (SC2) or a dry etch process that uses a plasma of a chlorine-containing gas (e.g., Cl₂ and/or BCl₃) and argon (Ar). After the first hard mask layer 246 and the first WFM layer 244 are removed from the first region 1000, the first BARC layer 248 may be removed from the second region 2000 using ashing or a selective etching process, as illustrated in FIG. 16.

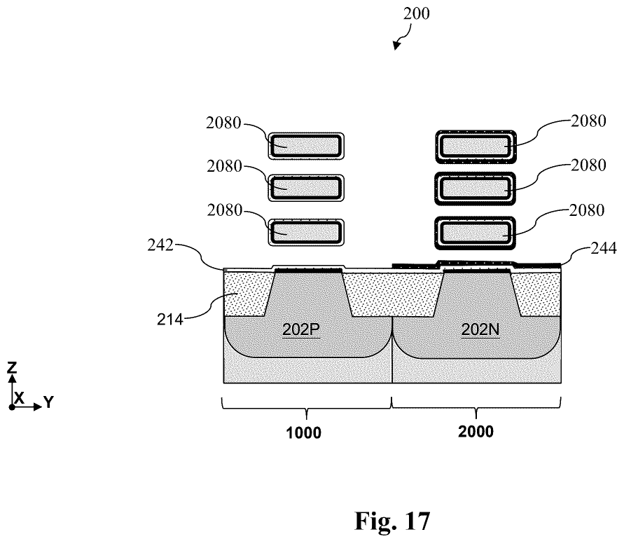

Referring to FIGS. 1 and 17, method 100 includes a block 116 where the first hard mask layer 246 is selectively removed from the second region 2000. After the removal of the first BARC layer 248 from the second region 2000, the remaining first hard mask layer 246 in the second region 2000 is exposed and may be removed using a wet etch process that uses ammonium hydroxide. As shown in FIG. 17, after operations at block 116, each of the first nanostructures 2080 in the first region 1000 is wrapped around by the interfacial layer 240 and the gate dielectric layer 242 and each of the second nanostructures 2080 in the second region 2000 is wrapped around by the interfacial layer 240, the gate dielectric layer 242, and the first WFM layer 244.

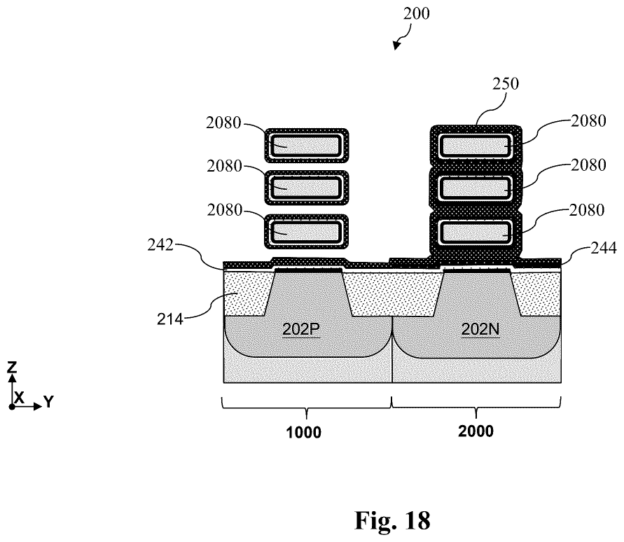

Referring to FIGS. 1 and 18, method 100 includes a block 118 where a second WFM layer 250 is deposited over the first region 1000 and the second region 2000. In some embodiments, the second WFM layer 250 may share the same composition with the first WFM layer 244. In these embodiments, the second WFM layer 250 is effectively a second layer of the first WFM layer 244. In some other embodiments, a composition of the second WFM layer 250 is different from a composition of the first WFM layer 244. In these embodiments, the second WFM layer 250 may function as a diffusion barrier layer to prevent diffusion of undesirable species, such as aluminum, into the first WFM layer 244. In some embodiments, the second WFM layer 250 may be a p-type WFM layer and may include titanium nitride (TiN), titanium silicon nitride (TiSiN), tantalum nitride (TaN), tungsten carbonitride (WCN), molybdenum (Mo), or other suitable p-type work function material. The second WFM layer 250 may be deposited using ALD. As show in FIG. 18, a thickness of the second WFM layer 250 is such that the spacing between two adjacent first nanostructures 2080 or second nanostructures 2080 are completely filled.

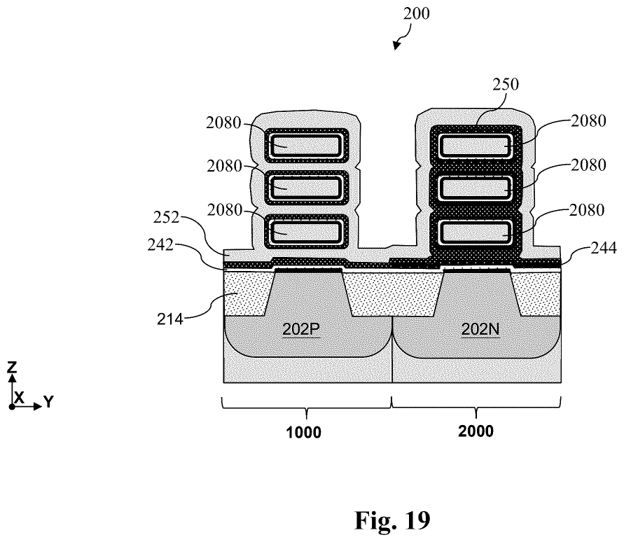

Referring to FIGS. 1 and 19, method 100 includes a block 120 where a second hard mask layer 252 is deposited over the first region 1000 and the second region 2000. The second hard mask layer 252 is formed of a material that may be selectively removed without substantially damaging the second WFM layer 250. In some embodiments, the second hard mask layer 252 is formed of a dielectric material (such as silicon oxide, aluminum oxide), or a semiconductor material (such as silicon or germanium or SiGe). In one embodiment, the second hard mask layer 252 includes aluminum oxide. The second hard mask layer 252 may be deposited using atomic layer deposition (ALD) or other suitable method. As shown in FIG. 19, the second hard mask layer 252 is formed to a thickness such that it completely fills the spacing between two adjacent first nanostructures 2080 in the first region 1000. Because the second WFM layer 250 fills the space between adjacent second nanostructures 2080, the second hard mask layer 252 does not extend vertically between two adjacent second nanostructures 2080.

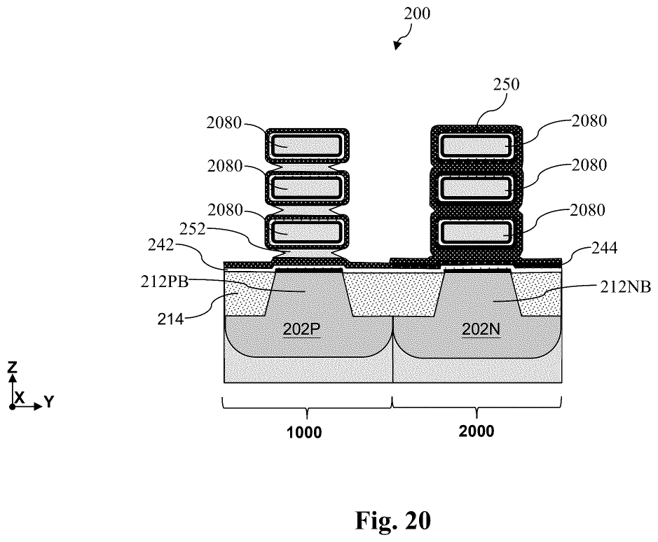

Referring to FIGS. 1 and 20, method 100 include a block 122 where the second hard mask layer 252 is trimmed. At block 122, a dry etch process or a wet etch process may be performed to remove the second hard mask layer 252 over the workpiece 200 other than the portions disposed between two adjacent first nanostructures 2080 in the first region 1000. The suitable etch process for block 122 may be selected based on the composition of the second hard mask layer 252. For example, when the second hard mask layer 252 includes aluminum oxide, ammonium hydroxide may be used to selectively etch the second hard mask layer 252. Put differently, operations at block 122 may remove the second hard mask layer 252 over the topmost surfaces and side surfaces of the first nanostructures 2080 to expose the second WFM layer 250 deposited thereover.

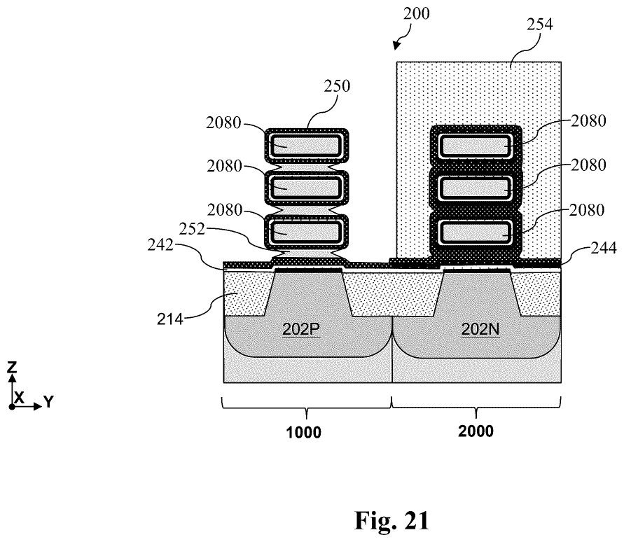

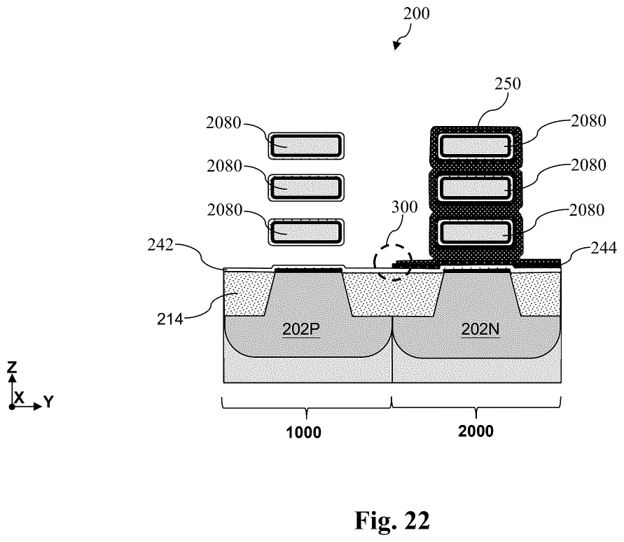

Referring to FIGS. 1, 21 and 22, method 100 includes a block 124 where the second hard mask layer 252 and the second WFM layer 250 are selectively removed from the first region 1000. To selectively remove the second hard mask layer 252 and the second WFM layer 250 from the first region 1000, a second BARC layer 254 is formed over the second region 2000 while the first region 1000 is exposed. In an example process, a blanket BARC layer is deposited over the first region 1000 and the second region 2000, and then a photoresist layer is deposited over the blanket BARC layer. The photoresist layer is pre-baked, patterned by exposure to a patterned radiation passing through or reflected from a mask, post-baked, and developed in a developing process using a developer, to form a patterned photoresist layer. The patterned photoresist layer is used as an etch mask to pattern the blanket BARC layer to form the second BARC layer 254, as shown in FIG. 21. With the second BARC layer 254 covering the second region 2000, the second hard mask layer 252 and the second WFM layer 250 over the first region 1000 are removed. The removal of the second hard mask layer 252 and the second WFM layer 250 may be performed using one or more etching process. For example, the second hard mask layer 252 may be removed using a wet etch process that uses ammonium hydroxide or a dry etch process that uses a chlorine-containing gas (e.g., Cl₂, CHCl₃, CCl₄, and/or BCl₃). The second WFM layer 250 may be removed using a wet etch process that includes a sulfuric acid hydrogen peroxide mixture (SPM), a mixture of ammonium hydroxide and hydrogen peroxide (SC1), or a mixture of hydrochloric acid and hydrogen peroxide (SC2) or a dry etch process that uses a plasma of a chlorine-containing gas (e.g., Cl₂ and/or BCl₃) and argon (Ar). After the second hard mask layer 252 and the second WFM layer 250 are removed from the first region 1000, the second BARC layer 254 may be removed from the second region 2000 using ashing or a selective etching process, as illustrated in FIG. 22.

Referring still to FIG. 22, because the first WFM layer 244 and the second WFM layer 250 are deposited and patterned in different sets of processes, a step-like feature 300 may be formed where, around the interface area between the first region 1000 and the second region 2000 (or between the n-type well 202N and the p-type well 202P), the second WFM layer 250 may fall short of covering an edge portion of the first WFM layer 244, leaving a top surface of a small edge portion of the first WFM layer 244 uncovered. As will be shown in subsequent figures and descriptions, further layers may be conformally deposited over the step-like feature 300 to continue the step-like shape.

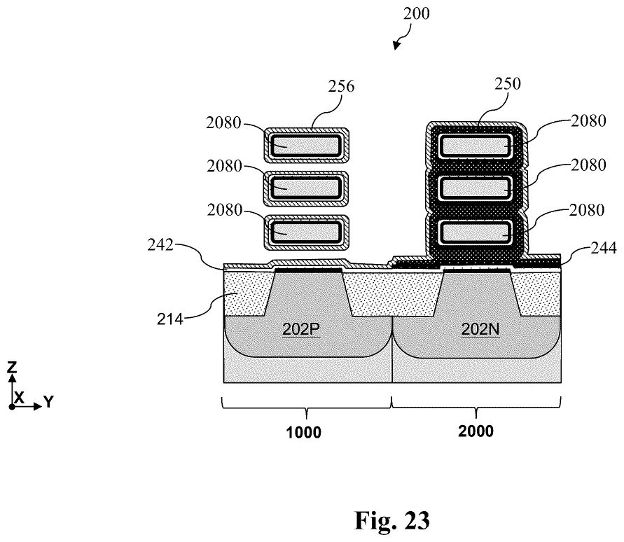

Referring to FIGS. 1 and 23, method 100 includes a block 126 where a third WFM layer 256 is deposited over the first region 1000 and the second region 2000. The third WFM layer 256 may have a different conductivity type from the first WFM layer 244 or the second WFM layer 250. In some embodiments, the third WFM layer 256 may be an n-type WFM layer and may include aluminum (Al), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), hafnium carbide (HfC), other n-type work function material, or combinations thereof. The third WFM layer 256 may be deposited using ALD. As show in FIG. 23, a thickness of the third WFM layer 256 is such that the spacing between two adjacent first nanostructures 2080 in the first region 1000 is not completely filled.

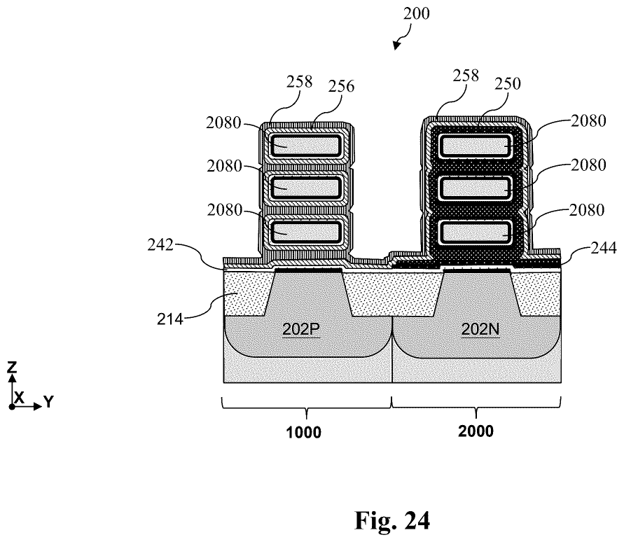

Referring to FIGS. 1 and 24, method 100 includes a block 128 where a glue layer 258 is deposited over the third WFM layer 256. In some embodiments, the glue layer 258 may include titanium nitride. In these embodiments, a composition of the glue layer 258 may be identical to that of the first WFM layer 244 or the second WFM layer 250. In some implementations, the glue layer 258 may be formed by ALD. In some instances, the glue layer 258 is deposited such that the space between adjacent first nanostructures 2080 in the first region 1000 is pinched off such that a subsequent layer may not be deposited between adjacent first nanostructures 2080.

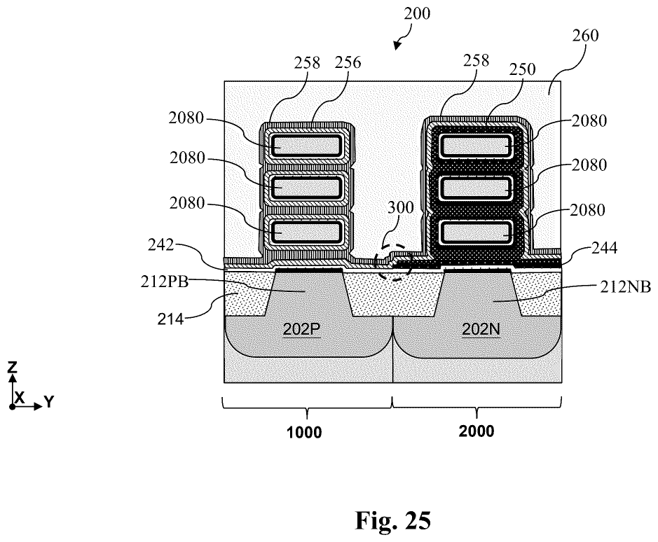

Referring to FIGS. 1 and 25, method 100 includes a block 130 where a gate cap layer 260 is deposited over the first region 1000 and the second region 2000. In some embodiments, the gate cap layer 260 may include tungsten (W) and may be deposited using ALD or CVD. As shown in FIG. 25, each of the third WFM layer 256, the glue layer 258, and the gate cap layer 260 extends and spans over the first region 1000 and the second region 2000, thereby form a common gate structure that engages the first nanostructures 2080 over the first region 1000 and the second nanostructures 2080 in the second region 2000.

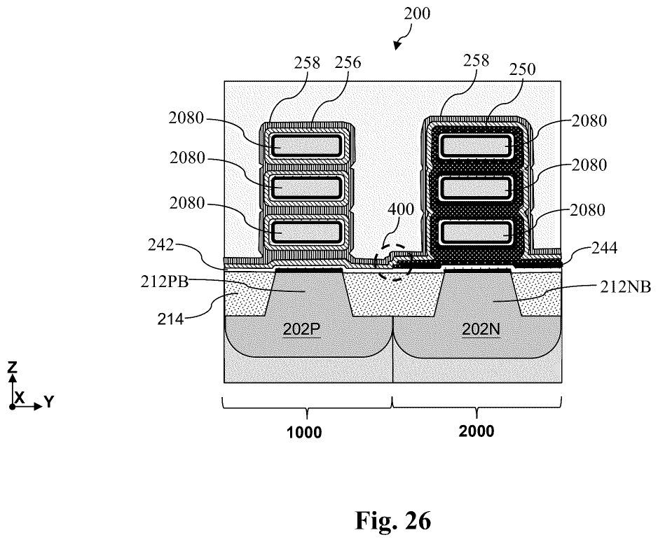

Referring still to FIG. 25, conformal deposition of the third WFM layer 256 and the glue layer 258 may continue to have the step-like shape of the step-like feature 300, which is resulted from separate patterning of the first WFM layer 244 and the second WFM layer 250. In some alternative embodiments shown in FIG. 26, the separate patterning of the first WFM layer 244 and the second WFM layer 250 may also form an enclosure step feature 400 where the second WFM layer 250 wraps over an edge of the first WFM layer 244. Like the step-like feature 300, subsequent conformal deposition of the third WFM layer 256 and the glue layer 258 may continue to have the step-like shape.

The present disclosure provides embodiments of processes for forming a gate structure of a multi-gate device. In one embodiment, a method is provided. The method includes receiving a workpiece that includes a first plurality of nanostructures over a first region of a substrate, and a second plurality of nanostructures over a second region of the substrate, depositing a gate dielectric layer over surfaces of each of the first plurality of nanostructures and each of the second plurality of nanostructures, depositing a first work function metal layer over the first plurality of nanostructures over the first region and the second plurality of nanostructures over the second region, depositing a first hard mask layer over the first work function metal layer, selectively removing the first hard mask layer and the first work function metal layer over the first region, selectively removing the first hard mask layer over the second region, after the selectively removing of the first hard mask layer over the second region, depositing a second work function metal layer over the first plurality of nanostructures over the first region and the second plurality of nanostructures over the second region, depositing a second hard mask layer over the second work function metal layer, selectively removing the second hard mask layer and the second work function metal layer over the first region, and depositing a third work function metal layer over the first plurality of nanostructures over the first region and the second plurality of nanostructures over the second region.

In some embodiments, the first work function metal layer and the second work function metal layer include titanium nitride (TiN), Titanium silicon nitride (TiSiN or TSN), or tungsten carbonitride (WCN). In some embodiments, a composition of the first work function metal layer and a composition of the second work function metal layer are the same. In some implementations, the first hard mask layer and the second hard mask layer include aluminum oxide. In some embodiments, the third work function metal layer includes aluminum (Al), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), or hafnium carbide (HfC). In some embodiments, the method further includes before the selectively removing of the first hard mask layer and the first work function metal layer over the first region, trimming the first hard mask layer, and before the selectively removing of the second hard mask layer and the second work function metal layer over the first region, trimming the second hard mask layer. In some embodiments, the method further includes depositing a glue layer over the third work function metal layer and depositing a gate cap layer over the glue layer. In some instances, the glue layer includes titanium nitride. In some embodiments, the gate cap layer includes tungsten (W).

In another embodiment, a method is provided. The method includes receiving a workpiece that includes a first plurality of nanostructures over a first base fin, and a second plurality of nanostructures over a second base fin spaced apart from the first base fin by an isolation feature, depositing a gate dielectric layer over surfaces of each of the first plurality of nanostructures and each of the second plurality of nanostructures, depositing a first work function metal layer over the first plurality of nanostructures and the second plurality of nanostructures and in contact with the gate dielectric layer, depositing a first hard mask layer over the first work function metal layer such that the first hard mask layer is spaced apart from the gate dielectric layer by the first work function metal layer, selectively removing the first hard mask layer and the first work function metal layer among the first plurality of nanostructures, selectively removing the first hard mask layer among the second plurality of nanostructures, depositing a second work function metal layer over the first plurality of nanostructures and the second plurality of nanostructures, depositing a second hard mask layer over the second work function metal layer, selectively removing the second hard mask layer and the second work function metal layer among the first plurality of nanostructures, and depositing a third work function metal layer to wrap around each of the first plurality of nanostructures and over the second work function metal layer over the second plurality of nanostructures.

In some embodiments, after the depositing of the gate dielectric layer, a portion of the gate dielectric layer extends continuously from over the first base fin to over the second base fin. In some embodiments, after the depositing of the first work function metal layer, a portion of the first work function metal layer extends continuously from over the first base fin to over the second base fin. In some embodiments, the selectively removing the first hard mask layer and the first work function metal layer among the first plurality of nanostructures includes trimming the first hard mask layer to expose portions of the first work function metal layer over a topmost surface and sidewalls of the first plurality of nanostructures, a topmost surface and sidewalls of the second plurality of nanostructures, and over the isolation feature, depositing a first patterning film to cover the second plurality of nanostructures and the second base fin, removing the first hard mask layer among the first plurality of nanostructures, removing the first work function metal layer among the first plurality of nanostructures, and removing the first patterning film. In some embodiments, the first hard mask layer includes aluminum oxide and the trimming includes an isotropic wet etch that uses ammonium hydroxide. In some embodiments, the selectively removing the second hard mask layer and the second work function metal layer among the first plurality of nanostructures includes trimming the second hard mask layer to expose portions of the second work function metal layer over a topmost surface and sidewalls of the first plurality of nanostructures, a topmost surface and sidewalls of the second plurality of nanostructures, and over the isolation feature, depositing a second patterning film to cover the second plurality of nanostructures and the second base fin, removing the second hard mask layer among the first plurality of nanostructures, removing the second work function metal layer among the first plurality of nanostructures, and removing the second patterning film.

In a further embodiment, a semiconductor structure is provided. The semiconductor structure includes a first base fin and a second base fin over a substrate, an isolation feature over the substrate and disposed directly between the first base fin and the second base fin, a first plurality of nanostructures disposed over the first base fin, a second plurality of nanostructures disposed over the second base fin, a gate dielectric layer wrapping around each of the first plurality of nanostructures, each of the second plurality of nanostructures as well as disposed over top surfaces of the first base fin, the second base fin, and the isolation feature, a first work function layer wrapping around each of the second plurality of nanostructures and disposed over the second base fin, a second work function layer wrapping around each of the second plurality of nanostructures and filling spaces among the second plurality of nanostructures, a third work function layer wrapping around each of the first plurality of nanostructures and over the second work function layer that wraps around the second plurality of nanostructures, a glue layer disposed on the third work function layer, and a gate cap layer over the glue layer. An interface exists between the first work function layer and the second work function layer.

In some embodiments, wherein the first work function layer and the second work function layer includes a p-type work function material. In some embodiments, the third work function layer includes an n-type work function material. In some implementations, a composition of the first work function layer and a composition of the second work function layer are the same. In some embodiments, the interface includes an oxide form of a metal composition in the first work function layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
receiving a workpiece comprising:
a first plurality of nanostructures over a first region of a substrate, and
a second plurality of nanostructures over a second region of the substrate;
depositing a gate dielectric layer over surfaces of each of the first plurality of nanostructures and each of the second plurality of nanostructures;
depositing a first work function metal layer over the first plurality of nanostructures over the first region and the second plurality of nanostructures over the second region;
depositing a first hard mask layer over the first work function metal layer;
selectively removing the first hard mask layer and the first work function metal layer over the first region;
selectively removing the first hard mask layer over the second region;
after the selectively removing of the first hard mask layer over the second region, depositing a second work function metal layer over the first plurality of nanostructures over the first region and the second plurality of nanostructures over the second region;
depositing a second hard mask layer over the second work function metal layer;
selectively removing the second hard mask layer and the second work function metal layer over the first region; and
depositing a third work function metal layer over the first plurality of nanostructures over the first region and the second plurality of nanostructures over the second region.

2. The method of claim 1, wherein the first work function metal layer and the second work function metal layer comprise titanium nitride (TiN), Titanium silicon nitride (TiSiN or TSN), or tungsten carbonitride (WCN).

3. The method of claim 1, wherein a composition of the first work function metal layer and a composition of the second work function metal layer are the same.

4. The method of claim 1, wherein the first hard mask layer and the second hard mask layer comprise aluminum oxide.

5. The method of claim 1, wherein the third work function metal layer comprises aluminum (Al), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), or hafnium carbide (HfC).

6. The method of claim 1, further comprising:
before the selectively removing of the first hard mask layer and the first work function metal layer over the first region, trimming the first hard mask layer; and
before the selectively removing of the second hard mask layer and the second work function metal layer over the first region, trimming the second hard mask layer.

7. The method of claim 1, further comprising:
depositing a glue layer over the third work function metal layer; and
depositing a gate cap layer over the glue layer.

8. The method of claim 7, wherein the glue layer comprises titanium nitride.

9. The method of claim 7, wherein the gate cap layer comprises tungsten (W).

10. A method, comprising:
receiving a workpiece comprising:
a first plurality of nanostructures over a first base fin, and
a second plurality of nanostructures over a second base fin spaced apart from the first base fin by an isolation feature;
depositing a gate dielectric layer over surfaces of each of the first plurality of nanostructures and each of the second plurality of nanostructures;
depositing a first work function metal layer over the first plurality of nanostructures and the second plurality of nanostructures and in contact with the gate dielectric layer;
depositing a first hard mask layer over the first work function metal layer such that the first hard mask layer is spaced apart from the gate dielectric layer by the first work function metal layer;
selectively removing the first hard mask layer and the first work function metal layer among the first plurality of nanostructures;
selectively removing the first hard mask layer among the second plurality of nanostructures;
depositing a second work function metal layer over the first plurality of nanostructures and the second plurality of nanostructures;
depositing a second hard mask layer over the second work function metal layer;
selectively removing the second hard mask layer and the second work function metal layer among the first plurality of nanostructures; and
depositing a third work function metal layer to wrap around each of the first plurality of nanostructures and over the second work function metal layer over the second plurality of nanostructures.

11. The method of claim 10, wherein, after the depositing of the gate dielectric layer, a portion of the gate dielectric layer extends continuously from over the first base fin to over the second base fin.

12. The method of claim 10, wherein, after the depositing of the first work function metal layer, a portion of the first work function metal layer extends continuously from over the first base fin to over the second base fin.

13. The method of claim 10, wherein the selectively removing the first hard mask layer and the first work function metal layer among the first plurality of nanostructures comprises:
trimming the first hard mask layer to expose portions of the first work function metal layer over a topmost surface and sidewalls of the first plurality of nanostructures, a topmost surface and sidewalls of the second plurality of nanostructures, and over the isolation feature;
depositing a first patterning film to cover the second plurality of nanostructures and the second base fin;
removing the first hard mask layer among the first plurality of nanostructures;
removing the first work function metal layer among the first plurality of nanostructures; and
removing the first patterning film.

14. The method of claim 13,
wherein the first hard mask layer comprises aluminum oxide,
wherein the trimming comprises an isotropic wet etch that uses ammonium hydroxide.

15. The method of claim 10, wherein the selectively removing the second hard mask layer and the second work function metal layer among the first plurality of nanostructures comprises:
trimming the second hard mask layer to expose portions of the second work function metal layer over a topmost surface and sidewalls of the first plurality of nanostructures, a topmost surface and sidewalls of the second plurality of nanostructures, and over the isolation feature;
depositing a second patterning film to cover the second plurality of nanostructures and the second base fin;
removing the second hard mask layer among the first plurality of nanostructures;
removing the second work function metal layer among the first plurality of nanostructures; and
removing the second patterning film.

16. A semiconductor structure, comprising:
a first base fin and a second base fin over a substrate;
an isolation feature over the substrate and disposed directly between the first base fin and the second base fin;
a first plurality of nanostructures disposed over the first base fin;
a second plurality of nanostructures disposed over the second base fin;
a gate dielectric layer wrapping around each of the first plurality of nanostructures, each of the second plurality of nanostructures as well as disposed over top surfaces of the first base fin, the second base fin, and the isolation feature;
a first work function layer wrapping around each of the second plurality of nanostructures and disposed over the second base fin;
a second work function layer wrapping around each of the second plurality of nanostructures and filling spaces among the second plurality of nanostructures;
a third work function layer wrapping around each of the first plurality of nanostructures and over the second work function layer that wraps around the second plurality of nanostructures;
a glue layer disposed on the third work function layer; and
a gate cap layer over the glue layer,
wherein an interface exists between the first work function layer and the second work function layer.

17. The semiconductor structure of claim 16, wherein the first work function layer and the second work function layer comprise a p-type work function material.

18. The semiconductor structure of claim 17, wherein the third work function layer comprises an n-type work function material.

19. The semiconductor structure of claim 17, wherein a composition of the first work function layer and a composition of the second work function layer are the same.

20. The semiconductor structure of claim 16, wherein the interface comprises an oxide form of a metal composition in the first work function layer.
